(19) United States
(12) Patent Application Publication
(10) Pub. No.: US 2009/0091479 A1
(43) Pub. Date: Apr. 9, 2009

(54) KEYPAD HAPTIC COMMUNICATION

(75) Inventor: Siddharth Sinha, Schaumburg, IL (US)

Correspondence Address: Mayback & Hoffman, P.A., 5722 S. Flamingo Road, #232, Fort Lauderdale, FL, 33330, US

(73) Assignee: MOTOROLA, INC., Schaumburg, IL (US)

(21) Appl. No.: 11/867,367

(22) Filed: Oct. 4, 2007

(51) Int. Cl. H03M 11/00

(52) U.S. Cl. 341/22

(57) ABSTRACT

The haptic communication device includes a housing; a keypad physically coupled to the housing, and a localized vibrator physically coupled to the keypad and operable to send a localized vibration to the keypad without causing the housing to vibrate substantially in comparison to the keypad. A controller communicatively coupled to a memory and the vibrator is operable to retrieve a haptic profile that includes a plurality of voltage displacements from the memory and communicate the haptic profile to the vibrator in response to recognizing an event. The haptic communication device is also able to record a haptic profile by receiving a vibrational force to its keypad, convert the vibrational force to a corresponding voltage, and store a representation of the voltage in memory as a portion of a haptic profile.

### FIELD OF THE INVENTION

This invention relates in general to wireless communication devices, and more particularly, to communication through localized keypad haptics.

### BACKGROUND OF THE INVENTION

The term “haptic” refers to anything relating to or based on the sense of touch. Recently, haptic capabilities have been added to wireless devices, such as cellular phones, to enhance the user experience of operating the device. By using haptics, a user of a cellular phone is, for instance, alerted of an incoming call by a vibration or a pattern of vibrations generated by a vibrator, usually an offset motor, within the phone.

Referring to FIG. 1, a conventional vibrator motor 100 comprises a cylindrical body 102, a longitudinal, rotating shaft 104, and an unbalanced, rotating counterweight 106. The cylindrical body 102 is held in place on a printed circuit board 108 by motor bracket 110. The counterweight 106 is attached to the protruding end of the shaft 104 on the vibrator motor 100. Operationally, the motor 100 is energized by a power source causing the shaft 104 and the counterweight 106 to rotate, resulting in the motor 100 vibrating and, consequently, the selective call receiver vibrating, thereby alerting the user.

The use of an offset motor to communicate signals has several disadvantages. Offset motors are relatively slow and imprecise when trying to communicate smaller signals, such as clicks or rapid beats. In addition, offset motors and other known haptic generators are not localized and cause the entire device to vibrate.

At least one device places piezo-electric actuators under the keypad. They are particularly advantageous in devices that use a smooth surface for the keypad, such as those devices utilizing a touch-screen display, where a user cannot physically tell if a button has been depressed. Piezo-electric actuators “click” on the back side of the touch-screen and provide physical feedback to the user. However, the actuators are currently limited in their use and in the information that they convey.

Currently, any haptic vibration responses (such as a click) or patterns (“profiles”) must be preloaded or otherwise electronically downloaded into the device. There is no way for the device to “listen” to a vibration pattern and save it as a profile.

Therefore, a need exists to overcome the problems with the prior art as discussed above.

### SUMMARY OF THE INVENTION

A device is disclosed for tactily communicating to a user of the device by sending, in response to an event, a pattern of signals that includes at least two voltage displacements to at least one of a plurality of piezo-electric elements located adjacent a keypad on a wireless device.

In accordance with another feature, the tactile communication includes receiving the pattern of signals from a memory communicatively coupled to the wireless device.

In accordance with a further feature, the pattern of signals are at least a portion of a haptic profile stored in memory.

In accordance with yet another feature of the present invention, the at least one piezo-electric element responds in dependence upon the pattern of signals to transfer vibration to the keypad substantially without transferring the vibration to other portions of the wireless device.

The present invention, according to an embodiment, provides a haptic communication device with a housing, a keypad physically coupled to the housing, a localized vibrator physically coupled to the keypad, a memory, and a controller communicatively coupled to the memory and to the localized vibrator and operable to retrieve a haptic profile from a plurality of haptic profiles in the memory, where each of the plurality of haptic profiles includes a plurality of voltage displacements, and communicate the retrieved haptic profile to the localized vibrator in response to recognizing an event.

In accordance with a feature of the present invention, the controller is operable to apply the plurality of voltage displacements within the retrieved haptic profile and vibrate the localized vibrator dependent upon differences of the plurality of voltage displacements.

In accordance with an additional feature of the present invention, the localized vibrator is a transducer capable of converting a physical contact with the keypad into an electrical output signal.

In accordance with yet another additional feature of the present invention, the controller is operable to store a representation of the electrical output signal in the memory as part of a haptic profile.

In accordance with a further feature of the present invention, the localized vibrator is operable to directly vibrate the keypad locally with a relatively maximum vibration and to indirectly vibrate the housing with a relatively minimum vibration.

The present invention, according to an embodiment, provides a method of recording a haptic profile, where the method includes the steps of applying a vibrational force to a keypad of a wireless device, converting the vibrational force to a corresponding voltage, and storing, in a memory, a representation of the voltage as a portion of a haptic profile.

In accordance with another feature, the present invention includes transferring the vibrational force through the keypad to a plurality of vibrational sensors and earning out the converting step with the vibrational sensors.

### BRIEF DESCRIPTION OF THE DRAWINGS

The accompanying figures, where like reference numerals refer to identical or functionally similar elements throughout the separate views, and which together with the detailed description below are incorporated in and form part of the specification, serve to further illustrate various embodiments and to explain various principles and advantages all in accordance with the present invention.

FIG. 1 is a perspective view of a conventional vibrator assembly attached to a printed circuit board.

FIG. 2 is elevational view of a mobile communication device with a front cover in place, according to an embodiment of the present invention.

FIG. 3 is an elevational view of a backside of the cover of FIG. 2, according to an embodiment of the present invention.

FIG. 4 is a process flow diagram of a haptic profile performance process, according to an embodiment of the present invention.

FIG. 5 is a block circuit diagram of a mobile communication device, according to an embodiment of the present invention.

FIG. 6 is a process flow diagram of a haptic profile recording process, according to an embodiment of the present invention.

### DETAILED DESCRIPTION

While the specification concludes with claims defining the features of the invention that are regarded as novel, it is believed that the invention will be better understood from a consideration of the following description in conjunction with the drawing figures, in which like reference numerals are carried forward. It is to be understood that the disclosed embodiments are merely exemplary of the invention, which can he embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention.

The terms “a” or “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The term “coupled,” as used herein, is defined as connected, although not necessarily directly, and not necessarily mechanically.

The present invention provides customized local tactile messaging using haptic components, which serve as actuators as well as sensors. The haptic components are localized, so that a tactile signal is felt in one area of the device and not along the entire device frame, as in prior-art configurations. In one embodiment of the present invention, a device is able to receive multimedia message service (MMS) messages (typically containing text, images and audio), as is well known in the art, but now has the ability to also receive and perform a customized haptics profile. For example, a user can send an MMS on Valentine's Day that causes the receiver's keypad to vibrate and feel like a heart beating. Embodiments of the present invention also provide the ability of assigning a customized haptics profile for each person in a phonebook, similar to a customized ring tone. Embodiments of the present invention also enhance the mobile gaming experience by making the keypad region vibrate according to the move made in the game by the player. For instance, a punch received in a game causes the user to get a punch-like feel from the keypad.

Referring now to FIG. 2, an exemplary electronic device 200 is shown. The specific electronic device 200, depicted in FIG. 2, is a cellular telephone. As will be clear, however, the present invention is not so limited and can also be used with other wireless devices and non-wireless devices that are triggered by an electrical event.

Wireless devices include, but are not limited to, PDA's, SmartPhones, Laptops, Palmtops, Pagers, Two-way Radios, Satellite Phones, and other communication devices. In one embodiment of the present invention, the cellular phone 200 is capable of receiving and transmitting radio frequency signals over a communication channel under a communications protocol such as CDMA, FDMA, TDMA, GPRS, and GSM or the like.

The cellular phone 200, as shown, includes a housing 202. The housing 202 includes an audio output grid 204, overlying a speaker (not shown) for generating voice and messaging information, audible alerts, and any other audio. An antenna 206 is provided for receiving and transmuting Radio Frequency (RF) communication signals and is attached to or integrated in the housing 202. A display 208 graphically depicts information, such as stored cellular phone numbers and caller ID information, to a user. An audio input aperture grid 210 is provided for coupling sound, including a user's utterances, to a microphone (not shown) disposed beneath the grid.

The cellular phone 200 includes a keypad 212. The keypad 212 can be any known or future developed keypad. In the embodiment shown, the keypad 212 is a monolithic surface. In other embodiments, the keypad 212 can include one or more individual keys or buttons that may control any of several functions such as menu selection, navigation, and data input. The monolithic keypad can be a touchscreen. Touchscreens, or touch panels, are display overlays that have the ability to display and receive information on the same screen. Such overlays allow a display to be used also as an input device. Many cellular phones are being built with one or more touchscreens as input/output components on the face of the phone.

The view of FIG. 2 shows the user-intractable side of the housing 202, referred to herein as the front surface. It is through this front surface that a user can enter information, dial numbers, engage and end communications, hear audio, input audio, and see graphics and other information. Regardless of the particular type of keypad 212 present on the phone 200, when in use, a user generally has his or her fingers (e.g. thumb) on the keypad region 212 of the phone 200.

The wireless device 200 interfaces with provider equipment through a wireless communication link established with base stations. The wireless device 200, according to the present example, works in conjunction with the provider equipment to provide a user with services such as telephone interconnect, short message service (SMS), MMS, dispatch or instant conferencing, circuit data, packet data, and combinations thereof as well as other data services.

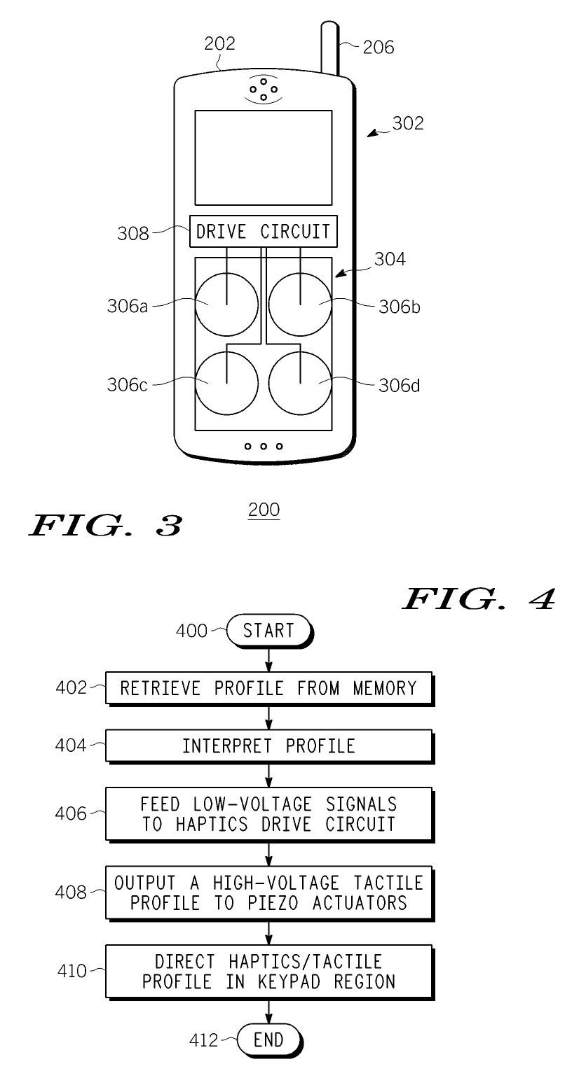

FIG. 3 shows the phone 200 with a lace portion 302 of the housing 202 removed, exposing a component side 304 of the face portion 302. Physically coupled to this back component side 304 of the housing face 302 is a plurality of haptic components 306a-d. The number of haptic components 306 is not limited to any particular number. In this embodiment, each of the four exemplary haptic components 306a-d are piezo-electric actuator/sensors.

Waving piezoelectric properties allows some materials (notably crystals and certain ceramics) to generate an electric charge in response to an applied mechanical stress. In 1880, Jacques and Pierre Curie discovered that, when deformed under mechanical stress, quartz crystals become electrically positively and negatively charged on prism-shaped surfaces. They called this behavior the piezoelectric effect. The piezoelectric effect is reversible, in that materials exhibiting the direct piezoelectric effect (the production of electricity when stress is applied) also exhibit the converse piezoelectric effect (the production of stress and/or strain when an electric field is applied). Often the term “transducer” is applied when the device acts in this dual capacity, but most piezo devices have this property of reversibility whether it is used or not.

Actuator

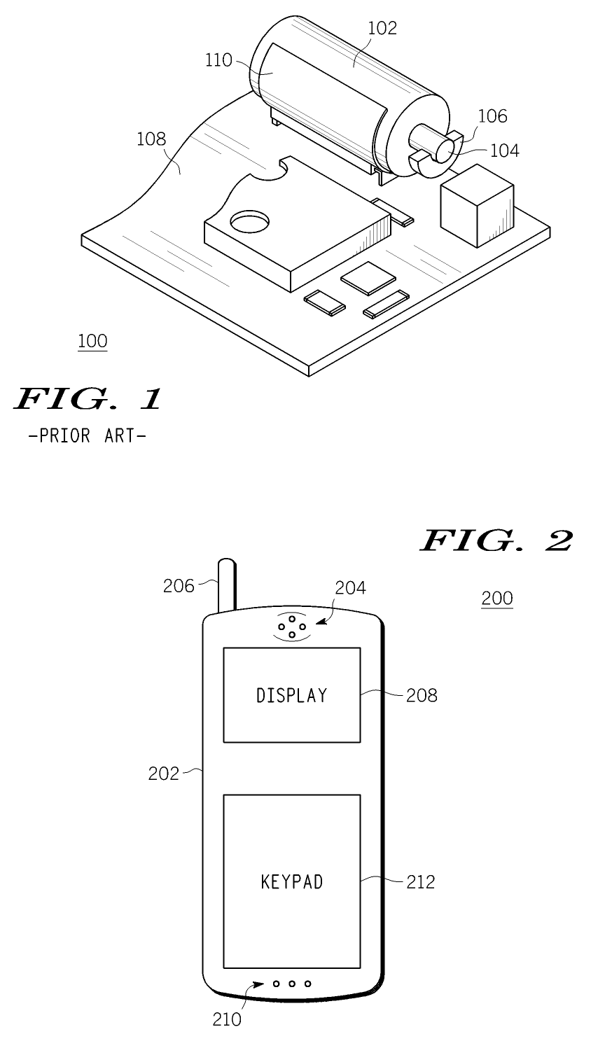

By applying an electric potential to any one or all of the haptic components 306a-d, a movement of the component 306a-d is created. By alternating the electric potential applied to the component 306a-d, a vibration can be created, which travels to the upper surface (see FIG. 1) of the face 302. The purpose and type (i.e., length, pattern, intensity) of vibration are dictated by the applied voltages and frequencies and can vary as desired.

Advantageously, the haptic components 306a-d are not strong enough to substantially vibrate the entire device, but are able to apply a relatively maximum vibration to the keypad 212 and to indirectly vibrate the housing 202 with a relatively minimum vibration. In other words, the entire housing could receive approximately 10% or less of the vibration measured at the keypad 212. This “localized” tactile signaling allows a user holding the keypad with a linger to detect individual operation of one or more of the haptic components 306a-d. Such localized haptic components 306a-d generate a customized tactile feel to enhance the user experience. For example, by applying a voltage to the components in the correct sequence and duration, different effects or sounds can be created.

FIG. 4 shows a process flow for utilizing one or more of the haptic components 306a-d. The flow starts at step 400 and moves directly to step 402. In step 402, a “profile” is retrieved from memory. A “profile,” as used in this context, is a predefined instruction or set of instructions for exciting at least one of the haptic components 306a-d to cause a particular vibration pattern. As an example, a haptic profile can be the drum beat of an audio or other media file, a heart beat, gunfire, an earthquake, knocking, drum beats, a punch, thunder, bubbles, and many other vibrations that can be mimicked by the actuators 306. The profile can include a vibration that lasts for any length of time. The haptic profile may be audio of an event like audio of a gun fire or could be a representation of the physical event, e.g., the gun recoil could be measured and recorded using a displacement sensor and this recording rather than the audio of the gun fire can be used as a haptics profile. Importantly, the haptics file need not be only the sound of the event: if the event can be physically recorded (displacement/acceleration/velocity), than that recording could be used as the customized haptics file. For instance, the profile can be a representation of a sound or event that is at least 1 second long or more.

Each profile includes a plurality of voltage displacement values that can be stored as a set of instructions that are, in step 404, interpreted by a processor that then causes, in step 406, corresponding low-voltage signals to be fed into a haptics drive circuit 308. The drive circuit 308, in step 408, amplifies the voltage and outputs a high-voltage tactile profile to the piezo actuators 306. In step 410, the haptics/tactile profile is felt by a user in the keypad region 212. If the profile is part of a media file, the profile can simultaneously be heard through the speaker 204 and/or seen on the display 208. If the audio file is used as the haptics profile, then it can be both played over the speaker 204 for audio and passed onto the actuators 306 for tactile signaling. However, if as explained above, the haptics file is not an audio file of the event, the haptics file is passed to actuators 306 for tactile signaling and a separate audio file may be used for sound effects of the message being conveyed. The process ends at step 412, once the profile has played to completion.

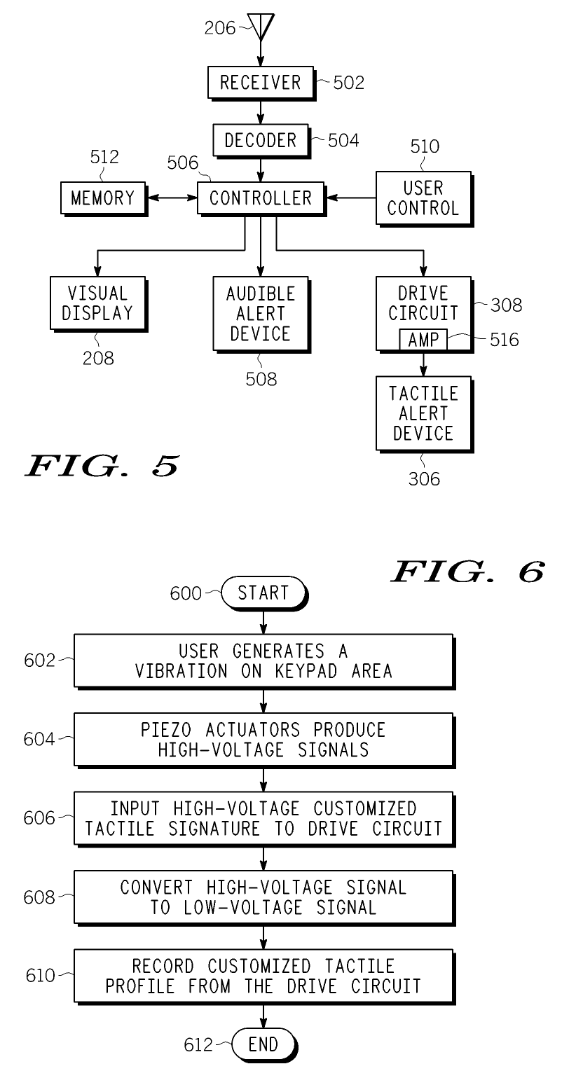

In one embodiment, where a sender sends a receiver a haptics SMS, step 402, where the haptics profile is first stored in memory, is skipped and a controller (506, shown in FIG. 5) directly passes the haptic profile to piezo-electric actuators 306.

Sensor

As stated above, the haptic components 306a-d may work in both directions. That is, a physical force applied to a haptic component 306 creates an electric field within the component 306. By tapping on the keypad 212, a vibration is created, which travels to the component side 304 of the face 302 and to any one or all of the haptic components 306a-d. When multiple components 306 are used, the tapping on the keypad 212 can be “localized,” where one of the components is vibrationally stimulated and the others are not.

Upon being vibrationally stimulated, the sensor 306 generates a resulting voltage. By recording one or a pattern of these voltages output from one or more sensors 306, a profile can be created that is a customized product of the user tapping on the keypad 212. This profile becomes a haptic profile that includes a plurality of voltage displacements. Advantageously, this provides an entirely new way for users to assign customized identifiers to incoming calls. For instance, if one or more callers are announced by a ring “tone,” which is a melody audibly played by the phone's speaker, the user can now assign vibrational beats to accompany or replace the melody. This, of course, is just one example of how a recorded vibration could be utilized and the invention is in no way limited thereto.

FIG. 5 shows a block circuit diagram of select components of the wireless device 200. The components include an RF receiver 502 for receiving and demodulating a signal, a decoder 504 for decoding the signal, and a processor/controller 506 for presenting an alert and message contained within a signal or an alert only through one of a plurality of output devices. These output devices include one or more of an audible alert (e.g., beep or tone) 508, a tactile alert device (i.e., message indicator) 306, and a visual alert 208. The tactile alert device(s) 306 is driven by a drive circuit 308 that includes an amplifier 516 operable to step voltages up that are going to the tactile alert device(s) 306. The drive circuit 308 also serves as a receiver and steps down voltages coming from the tactile alert device(s) 306. Additionally, the alert may be presented in response to selection of a user control 510 (e.g., pushing a button or moving a slide switch). A memory 512 stores information that includes representations of alert (i.e., haptic) profiles or instructions for causing profiles to be played on one or more of the output devices 208, 508, and 306. The memory 512 can hold a plurality of different profiles (which are representations of voltage patterns) that can be called up and followed from the stimulation of any triggering event. As one example, a heartbeat profile may be programmed by the user to be initiated when a specific person calls.

FIG. 6 is a flow diagram of a vibration-capturing and corresponding profile-storage process, in accordance with one embodiment of the present invention. The flow starts at step 600 and moves directly to step 602, where a user taps, or otherwise vibration ally excites, the keypad area 212 of the phone 200. As a direct effect of the tapping, in step 604, the piezo actuators 306, which now function as sensors, deform to produce high-voltage signals. In step 606, the high-voltage customized tactile signature resulting from the vibration is input to the drive circuit 308 from the piezo elements 306. Within the drive circuit is an amplifier 516 that, in step 608, converts the high-voltage signal to a low-voltage signal. The customized tactile profile from the drive circuit 514 is, in step 610, recorded to create a customized haptics profile. The recording can, for instance, be performed by the recording feature of a media player. In step 612, the process ends.

Computer Program Product

In addition to the memory 512, haptic profiles may also be embedded in a computer program product, or computer readable medium, which comprises all the features enabling the implementation of the methods described herein, and which—when loaded in a computer system—is able to catty out these methods. Computer program in the present context means any expression, in any language, code or notation, of a set of instructions intended to cause a system having an information processing capability to perform a particular function either directly or after either or both of the following a) conversion to another language, code or, notation; and b) reproduction in a different material form.

The computer readable medium may include non-volatile memory, such as ROM, flash memory, disk drive memory, CD-ROM, SIM card, arid other permanent storage. Additionally, a computer medium may include, for example, volatile storage such as RAM, buffers, cache memory, and network circuits.

The terms program, software application, and the like as used herein, are defined as a sequence of instructions designed for execution on a computer system. A program, computer program, or software application may include a subroutine, a function, a procedure, an object method, an object implementation, an executable application, an applet, a servlet, a source code, an object code, a shared library/dynamic load library and/or other sequence of instructions designed for execution on a computer system.

Conclusion

As should now be clear, embodiments of the present invention provide an advantage over prior art devices by providing a haptic experience localized to the keypad of a mobile phone by utilization of the haptic components as both sensors and actuators to capture and render, respectively, haptic patterns, where the haptic experience is customizable and can be driven by software events (e.g., synchronized with a music player).

Non-Limiting Examples

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments, and it is intended that the appended claims cover any and ail such applications, modifications, and embodiments within the scope of the present invention.

What is claimed is:

1. A haptic communication device comprising:
a housing;
a keypad physically coupled to the housing;
a localized vibrator physically coupled to the keypad;
a memory; and
a controller communicatively coupled to the memory and to the localized vibrator and operable to retrieve a haptic profile from a plurality of haptic profiles in the memory, where each of the plurality of haptic profiles includes a plurality of voltage displacements, and communicate the retrieved haptic profile to the localized vibrator in response to recognizing an event.

2. The haptic communication device according to claim 1, wherein:
the controller is operable to apply the plurality of voltage displacements within the retrieved haptic profile and vibrate the localized vibrator dependent upon differences of the plurality of voltage displacements.

3. The haptic communication device according to claim 2, wherein:
the localized vibrator is a transducer capable of converting a physical contact with the keypad into an electrical output signal.

4. The haptic communication device according to claim 3, wherein:
the controller is operable to store a representation of the electrical output signal in the memory as part of a haptic profile.

5. The haptic communication device according to claim 1, wherein:
the keypad has a user-facing surface area; and
the localized vibrator is a plurality of piezo-electric actuators distributed over the surface area of the keypad.

6. The haptic communication device according to claim 1, further comprising:
the keypad has a user-facing side and a component-facing side: and
the localized vibrator is physically coupled to the component-facing side.

7. The haptic communication device according to claim 1, wherein:
the controller communicates the haptic profile to the localized vibrator from a controller output; and
a voltage amplifier is electrically connected between the controller output and the localized vibrator.

8. The haptic communication device according to claim 1, wherein:
the haptic profile is a representation of a sound that is at least 1 second in duration.

9. The haptic communication device according to claim 1, wherein:
the localized vibrator is operable to directly vibrate the keypad locally with a relatively maximum vibration and to indirectly vibrate the housing with a relatively minimum vibration.

10. A method for tactily communicating to a user of a wireless device, the method comprising:
sending, in response to an event, a pattern of signals that includes at least two voltage displacements to at least one of a plurality of piezo-electric elements located adjacent a keypad on a wireless device.

11. The method according to claim 10, wherein the sending is performed by:
receiving the pattern of signals from a memory communicatively coupled to the wireless device.

12. The method according to claim 10, wherein:
the pattern of signals are at least a portion of a haptic profile stored in memory.

13. The method according to claim 10, wherein
the at least one piezo-electric element responds in dependence upon the pattern of signals to transfer vibration to the keypad substantially without transferring the vibration to other portions of the wireless device.

14. The method according to claim 10, wherein:
the pattern of signals is a representation of a sound of at least one of:
gunfire;
a heart beat;
an earthquake;
knocking;
drum beats;
thunder; and
bubbles.

15. A method of recording a haptic profile, the method comprising:
applying a vibrational force to a keypad of a wireless device;
converting the vibrational force to a corresponding voltage; and
storing, in a memory, a representation of the voltage as a portion of a haptic profile.

16. The method according to claim 15, further comprising:
transferring the vibrational force through the keypad to a plurality of vibrational sensors and carrying out the converting step with the vibrational sensors.

17. The method according to claim 16, wherein:
the vibrational sensors are piezo-electric elements.

18. The method according to claim 15, further comprising:
performing the converting step with at least one piezo-electric element.

19. The method according to claim 15, further comprising:
reading the haptic profile from memory; and
performing the profile.
